(19) United States
(12) Patent Application Publication
(10) Pub. No.: US 2021/0184054 A1
(43) Pub. Date: Jun. 17, 2021

(54) SEMICONDUCTOR DEVICE AND ITS MANUFACTURING METHOD

(71) Applicant: RENESAS ELECTRONICS CORPORATION, Tokyo (JP)

(72) Inventors: Hironobu MIYAMOTO, Ibaraki (JP); Masami SAWADA, Ibaraki (JP); Tatsuya USAMI, Ibaraki (JP); Tomoo NAKAYAMA, Ibaraki (JP)

(21) Appl. No.: 16/951,692

(22) Filed: Nov. 18, 2020

(30) Foreign Application Priority Data
Dec. 13, 2019 (JP) 2019-225767

(51) Int. Cl. H01L 29/861; H01L 29/24; H01L 29/66

(52) U.S. Cl. CPC H01L 29/861; H01L 29/6609; H01L 29/24

(57) ABSTRACT

A gallium oxide diode includes: a gallium oxide substrate having an n-type gallium oxide drift layer; an anode electrode of a metal film formed over a front surface of the n-type gallium oxide drift layer; a cathode electrode formed over a rear surface of the gallium oxide substrate; and a reaction layer of a metal oxide film of p-type conductivity formed between the anode electrode and the n-type gallium oxide drift layer. Further, a manufacturing method of a gallium oxide diode includes steps of forming an anode electrode of a metal film over an n-type gallium oxide drift layer formed over a gallium oxide substrate; and forming a reaction layer between the anode electrode and the n-type gallium oxide drift layer by performing a heat treatment to the gallium oxide substrate after forming the anode electrode, the reaction layer being made of a metal oxide film with p-type conductivity.

### CROSS-REFERENCE TO RELATED APPLICATION

The present application claims priority from Japanese Patent Application No. 2019-225767 filed on Dec. 13, 2019, the content of which is hereby incorporated by reference into this application.

### TECHNICAL FIELD OF THE INVENTION

The present invention relates to a semiconductor device provided with a diode and its manufacturing method, particularly, to an effective technique appliable to a diode configured by using gallium oxide (Ga₂O₃) as a semiconductor material.

### BACKGROUND OF THE INVENTION

As a semiconductor material having a wide band gap, in a device using gallium oxide (Ga₂O₃) as a semiconductor material, a Ga₂O₃ substrate can be manufactured by an EFG (Edge-defined Film-fed Growth) method, which has results of mass production of sapphire substrates. Since the Ga₂O₃ substrate has a breakdown field strength three times larger than that of a silicon carbide substrate, the Ga₂O₃ substrate is expected to have the same or higher performance at a lower cost than the silicon carbide substrate, which brings active research and development.

Since on-resistance that is an important performance index of the diode is determined by resistance of a drift layer, use of properties of the drift layer equal to or more than ten times a breakdown field strength of silicon (0.5 MV/cm) brings a reduction in resistance due to an increase in a concentration of the drift layer (e.g., a concentration of 1×10¹⁶ cm⁻³ to 1×10¹⁷ cm⁻³) (see FIG. 2 in Non-Patent Document 1 (K. Konishi et al., Appl. Phys. Lett. 110, 103506 (2017))). In this state, a withstand voltage in a reverse direction is determined, unlike a silicon device, not by dielectric breakdown due to an electric field but by an increase in a leakage current due to a tunnel current (see FIG. 3 in Non-Patent Document 1). Since a p-type layer cannot be formed with gallium oxide (Ga₂O₃) in order to suppress the tunnel current, a gate material having a large barrier height and a process as shown in FIG. 4 of Non-Patent Document 1 have been used as one of some solutions. A metal material such as platinum (Pt), gold (Au), or nickel (Ni) having a large barrier height is used as an anode electrode, and an attempt of a heterojunction to a dissimilar oxide semiconductor (e.g., nickel oxide (NiO)) with p-type properties has also been reported (see FIGS. 6 and 7 in Non-Patent Document 2 (Y. Kokubun et al., Appl. Phys. Express 9, 091101 (2016))).

### SUMMARY OF THE INVENTION

As a result of examining improvement of characteristics of a diode configured by using gallium oxide (Ga₂O₃) as a semiconductor material, the inventors of the present application have found the following concerns.

Pt and Au, which are noble metals each having a large work function and a barrier height of 1.0 to 1.5 eV, are effective in reducing a reverse current of a gate, but their adhesive forces are small (weak) since they do not react with gallium oxide (Ga₂O₃). Consequently, when a wiring wire (s) is bonded to an anode electrode, a concern about the anode electrode being peeled off the wiring wire may occur. Therefore, a concern arises about a yield decreasing in assembling a package(s) for sealing the diode or in mounting a device(s).

Further, in order to improve the adhesion properties of the anode electrode, when a heat treatment is applied by using a metal (e.g., titanium (Ti)) capable of forming a reaction layer at an interface between the anode electrode and gallium oxide (Ga₂O₃), a reaction layer of titanium oxide (TiO) is formed at (on) the interface, which brings occurrence of oxygen deficiency on a gallium oxide (Ga₂O₃) side. Although the adhesion properties are improved, the oxygen deficiency has a property of a donor, so that a concern arises about a high-concentration n-type donor layer being formed at the interface and a leakage current being increased in addition to a small barrier height of titanium (Ti).

Other problems and new features will be apparent from descriptions of this specification and the drawings.

A semiconductor device according to an embodiment includes: a gallium oxide substrate having an n-type gallium oxide drift layer; an anode electrode formed over a front surface of the n-type gallium oxide drift layer and made of a metal film; a cathode electrode formed over a rear surface of the gallium oxide substrate; and a reaction layer formed between the anode electrode and the n-type gallium oxide drift layer and made of a metal oxide film indicating p-type conductivity.

The reaction layer is set to have: a thickness of 5 nm or more which suppresses a tunnel current; and a thickness of 50 nm or less which suppresses, up to 10% or less, an increase in resistance values during forward energization.

Further, a manufacturing method of a semiconductor device according to an embodiment includes the steps of: preparing a gallium oxide substrate having an n-type gallium oxide drift layer; forming a metal film (Ni, Cu, CuAl, ZnRh) as a material of an anode electrode over the gallium oxide substrate; and forming a reaction layer between the metal anode electrode and the n-type gallium oxide drift layer by performing a heat treatment to the gallium oxide substrate after forming the metal film, the reaction layer being made of a metal oxide film with p-type conductivity.

The semiconductor device according to the embodiment makes it possible to improve a yield at times of package assembly and device mounting in order that the adhesion properties of the anode electrodes is improved by the reaction layer made of a metal oxide film. In addition, since the reaction layer indicates a p-type, a barrier layer becomes thicker and a gate leakage current due to a tunnel phenomenon is reduced, which brings realization of a higher withstand voltage. Further, setting the thickness of the reaction layer to a predetermined thickness makes it possible to suppress an increase in resistance values during the forward energization.

### BRIEF DESCRIPTION OF THE DRAWINGS

FIG. 1 is a sectional view of a main part of a semiconductor device including a gallium oxide diode according to a first embodiment;

FIG. 2 is a plan view corresponding to FIG. 1;

FIG. 3 is a sectional view of a main part showing a manufacturing process of the semiconductor device including the gallium oxide diode according to the first embodiment;

FIG. 4 is a sectional view of the main part showing the manufacturing process of the semiconductor device subsequently to FIG. 3;

FIG. 5 is a sectional view of the main part showing the manufacturing process of the semiconductor device subsequently to FIG. 4;

FIG. 6 is a sectional view of the main part showing the manufacturing process of the semiconductor device subsequently to FIG. 5;

FIG. 7 is a sectional view of a main part of a semiconductor device including a gallium oxide diode which is a modification example of the first embodiment;

FIG. 8 is a sectional view of a main part of a semiconductor device including a gallium oxide diode according to a second embodiment;

FIG. 9 is a plan view corresponding to FIG. 8;

FIG. 10 is a sectional view of a main part showing a manufacturing process of the semiconductor device including the gallium oxide diode according to the second embodiment;

FIG. 11 is a sectional view of the main part showing the manufacturing process of the semiconductor device subsequently to FIG. 10;

FIG. 12 is a sectional view of the main part showing the manufacturing process of the semiconductor device subsequently to FIG. 11;

FIG. 13 is a sectional view of the main part showing the manufacturing process of the semiconductor device subsequently to FIG. 12;

FIG. 14 is a sectional view of the main part showing the manufacturing process of the semiconductor device subsequently to FIG. 13;

FIG. 15 is a sectional view of the main part showing the manufacturing process of the semiconductor device subsequently to FIG. 14; and

FIG. 16 is a comparative view showing calculated values of reverse voltage dependence of respective leakage currents of the diode according to the first embodiment and a diode of the conventional example.

### DESCRIPTIONS OF THE PREFERRED EMBODIMENTS

A semiconductor device according to an embodiment will be described in detail with reference to the drawings. Incidentally, in the specification and drawings, the same constituent elements or corresponding constituent elements are denoted by the same reference numerals, and duplicate descriptions will be omitted. In addition, at least a part of the embodiment and a part of each modification example may be arbitrarily combined with each other. Incidentally, in each sectional view, diagonal lines indicating that each region therein is not hollow may be omitted in order to make the drawings easier to see. When indicating the hollow, the specification will set forth such an indication separately.

Each of the symbols “⁻” and “⁺” represents a relative concentration of each impurity whose conductive type is an n-type or p-type. For example, in a case of then-type impurity, an impurity concentration increases in order of “n⁻⁻”, “n⁻”, “n”, “n⁺”, and “n⁺⁺”.

### Embodiment 1

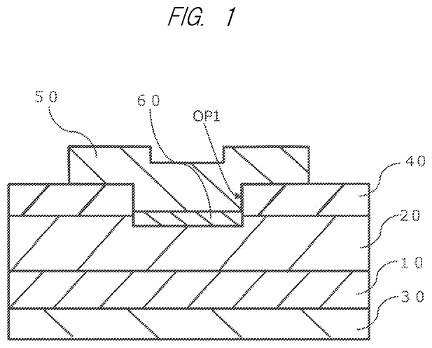

FIG. 1 shows a sectional view of a main part of a gallium oxide diode according to a first embodiment. A gallium oxide diode includes: a substrate 10 made of n⁺-type gallium oxide (Ga₂O₃); a drift layer 20 made of n-type gallium oxide (Ga₂O₃) that has been formed by, for example, an epitaxial growth method on the substrate 10; a cathode electrode 30 formed on a rear surface of the substrate 10; an insulating film 40 formed on a front surface of the drift layer 20; and an anode electrode 50 formed so as to contact with the drift layer 20 through an opening OP1 of the insulating film 40.

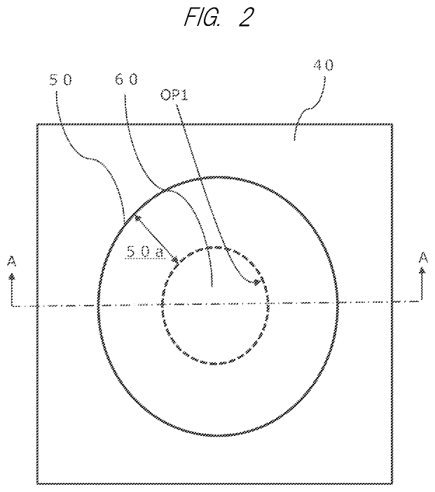

As shown in FIG. 2, the opening OP1 of the insulating film 40 has a circular shape in a plan view, and an end portion 50a of the anode electrode 50 is formed so as to extend from an edge of the opening OP1 shown by a dotted line to an upper portion (outer periphery) of the insulating film 40 and to be concentrically hung over from its outside. This end portion 50a functions as a field plate electrode, thereby suppressing a concentration of an electric field near an interface between the anode electrode 50 and the drift layer 20 on an outer peripheral portion of the opening OP1.

Incidentally, an A-A cross-section of FIG. 2 corresponds to FIG. 1. The first embodiment has a feature in which an electrode material used for the anode electrode 50 is thermally oxidized to forma reaction layer 60 made of an oxide semiconductor having p-type conductivity (e.g., NiGaO, Cu₂GaO, CuAlGaO₂), the reaction layer being formed at the interface between the anode electrode 50 and the drift layer 20. The reaction layer 60 is formed by: using, for example, a metal film (Ni, Cu, CuAl) such as nickel, copper, or copper-aluminum alloy as an electrode material of the anode electrode 50; forming the metal film to be an electrode material on the front surface of the drift layer 20; and then performing a heat treatment thereto. Thickness of the reaction layer 60 is set to: such a thickness of 5 nm or more as to reduce a tunnel current; and such a thickness of 50 nm or less that an increase in resistance during forward energization is suppressed up to 10% or less. The thickness of the reaction layer 60 can be controlled by heat treatment temperature and heat treatment time.

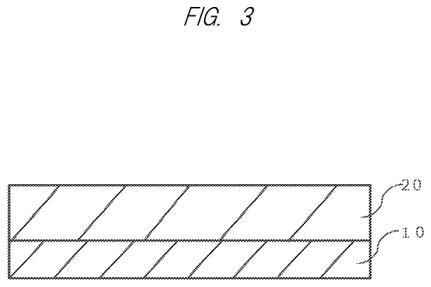

Next, a manufacturing method of the gallium oxide diode according to the first embodiment shown in FIG. 1 will be described with reference to FIGS. 3 to 6.

First, as shown in FIG. 3, the drift layer 20, which is an n⁻-type semiconductor layer made of gallium oxide (Ga₂O₃), is formed on a main surface of the substrate 10 made of Ga₂O₃ by an epitaxial growth method. The thickness of the drift layer 20 is, for example, 10 microns. The drift layer 20 contains n-type impurities with an impurity concentration lower than that of the Ga₂O₃ substrate 10. An impurity concentration of the drift layer 20 depends on a rated withstand voltage of an element and is, for example, 1×10¹⁶ cm⁻³. The drift layer 20 serves as a current path that flows in a vertical direction (thickness direction of the substrate 10) in the diode formed later.

In addition, n-type impurities whose concentration has relatively high are introduced into the substrate 10. For example, tin (Sb) is used as a suitable material for these n-type impurities, and an impurity concentration of the substrate 10 is, for example, 5×10¹⁸ cm⁻³.

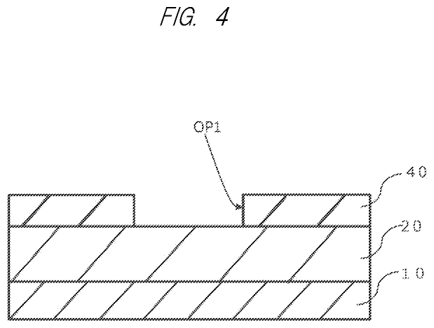

Next, as shown in FIG. 4, the insulating film 40 having the opening OP1 is formed on the upper surface of the drift layer 20. The insulating film 40 is a silicon oxide (SiO₂) film that is formed so as to expose a front surface of the drift layer 20 into a circular shape in a plan view and that has, for example, an opening having a diameter of 1.0 mm. The insulating film 40 can be formed by, for example, a TEOS (Tetra Ethyl Ortho silicate) film using a CVD (Chemical Vapor Deposition) method, and by using a normal photolithography technique and an etching method to pattern the TEOS film.

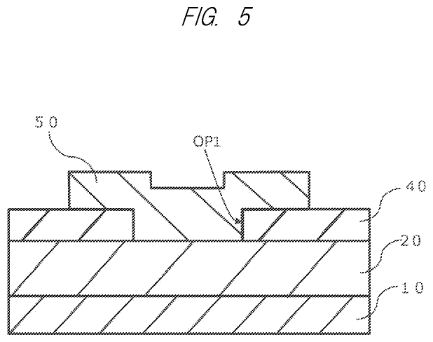

Next, as shown in FIG. 5, the anode electrode 50 is formed so as to be concentrically hung over outside from the opening OP1 around the front surface of the drift layer 20 that is exposed from the insulating film 40. As the electrode material of the anode electrode 50, for example, a nickel (Ni) film can be used as a suitable material. The nickel (Ni) film has a thickness of, for example, 0.2 μm and is formed into such a planar pattern as to be hung over outward by about 10 μm from the opening OP1.

Further, the anode electrode 50 can be formed by a lift-off method using a resist pattern as a base having a thickness of about 2 μm after forming the nickel (Ni) film on the entire surface of the insulating film 40 including the opening OP1 by vapor deposition.

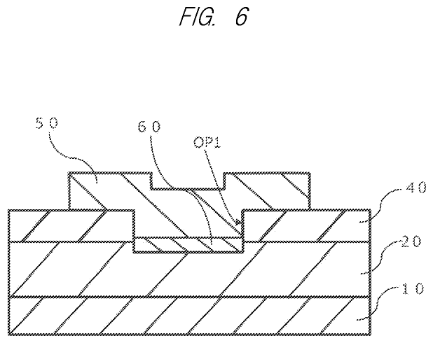

Next, under a state where the anode electrode is formed, the substrate 10 is subjected to a heat treatment at 500° C. for 30 minutes in a nitrogen (N₂) atmosphere and, as shown in FIG. 6, the reaction layer 60 made of NiGaO is thereby formed at the interface between the electrode 50 and the drift layer 20 in the opening OP1.

Next, the rear surface of the substrate 10 is sequentially subjected to grinding, polishing, and CMP (Chemical Mechanical Polishing) steps, and the thickness of the substrate 10 is thereby reduced, for example, from an initial thickness of 650 μm to a thickness of 200 μm.

Next, as shown in FIG. 1, the cathode electrode 30 is formed on the rear surface of the thinned substrate 10. The cathode electrode 30 can be formed, for example, by sequentially laminating a titanium (Ti) film or a gold (Au) film on the rear surface of the substrate 10 and then subjecting a heat treatment at 300° C. for 1 minute to the lamination. By performing the above steps, the gallium oxide diode according to the first embodiment is formed.

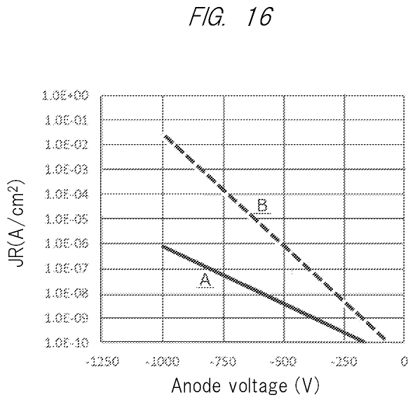

In order to explain a main effect of the gallium oxide diode according to the first embodiment, calculated values of the reverse voltage dependence of the leakage current in the diode are shown in FIG. 16.

For example, in a diode in which the drift layer 20 formed of an epitaxial layer of gallium oxide has an impurity concentration of 1×10¹⁶ cm⁻³ and a thickness of 10 μm and the anode electrode 50 has a barrier height of 1.1 eV, if a guideline of the withstand voltage is set to a leak current density of 1×10⁻⁴ A/cm² standardized by a diode area, a conventional diode has a withstand voltage of about 750 V due to an influence of the tunnel current as shown by a dotted line B, whereas the diode of the first embodiment in which the reaction layer 60 having a thickness of about 50 nm is formed has a withstand voltage improved up to 1000 V or more as shown by a solid line A.

On the contrary, if the withstand voltages are about the same, the diode of the first embodiment has a smaller leakage current. Further, the increase in the resistance value in the forward direction causes a current to flow through the diode when a forward voltage is applied to the anode electrode 50 (also referred to as a gate). When a p-type NiGaO reaction layer is formed at the interface between the anode electrode 50 and the drift layer 20, electrons are injected into the reaction layer 60 from the drift layer 20 formed of n-type Ga₂O₃ during the energization to generate a current. However, its electron concentration is low, so that a resistance R becomes high in value and a loss (R×I²) during the energization of the diode increases.

However, as shown by the calculated values in FIG. 16, reducing the thickness of the reaction layer 60 to 50 nm or less makes it possible to suppress a rate of an increase in the resistance R (Ri/R0) up to 10% or less. Further, reducing the thickness of the reaction layer 60 to 25 nm or less makes it possible to suppress the rate of the increase in the resistance R (Ri/R0) up to 5% or less.

Further, forming the reaction layer 60 at the interface between the anode electrode 50 and the drift layer makes it possible to prevent the anode electrode from peeling off when a wire bonding wiring(s) is formed on the anode electrode 50 and to improve a yield of the semiconductor device. Therefore, according to a diode structure and a diode manufacturing method of the first embodiment, a diode reducing a reverse-direction leakage current, hiving a high withstand voltage, and suppressing an increase in on-resistance can be manufactured with a good yield

### First Modification Example

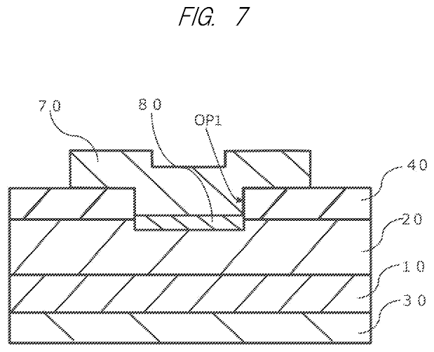

FIG. 7 shows a first modification example of the first embodiment. A first modification example is different from the first embodiment in a material of the anode electrode and metal oxide configuring the reaction layer. In the first modification example, an electrode material of the anode electrode applies a metal material (Al, Zr, Y, Hf) having electron affinity smaller than that of gallium oxide (Ga₂O₃) when oxidized.

As shown in FIG. 7, for example, when an aluminum (Al) film is used as the anode electrode 70, a reaction layer 80 made of AlGaO is formed by: forming the aluminum film on the front surface of the drift layer 20 exposed from the insulating film 40; then patterning the aluminum film in the same manner as in the first embodiment to form the anode electrode 70; and thereafter subjecting a heat treatment thereto. Here, an Al composition in the reaction layer 80 made of AlGaO gradually decreases from an interface side of Al to an interface side of Ga₂O₃ in a laminated structure of Al (anode electrode)/AlGaO (reaction layer)/Ga₂O₃ (drift layer), thereby leading to zero at the interface reaching Ga₂O₃.

Even when zirconium (Zr), yttrium (Y), or hafnium (Hf) other than aluminum is used as the electrode material of the anode electrode 70, the same effect as that of the first embodiment can be obtained. In this case, each material of metal oxide configuring the reaction layer 80 is ZrGaO₂, YGaO, or HfGaO.

### Second Embodiment

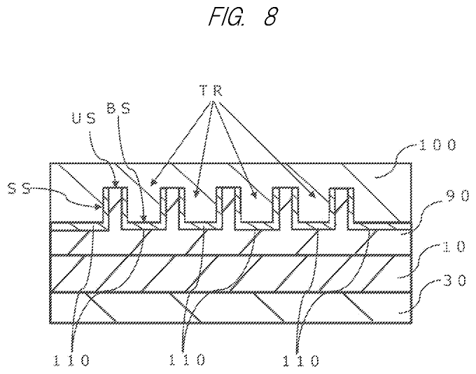

FIG. 8 shows a cross-section of a gallium oxide diode of a second embodiment. A main feature point of a second embodiment is to form a stripe-shaped trench(es) on a main surface of the drift layer.

Adrift layer 90 made of n-type Ga₂O₃ is formed on a substrate 10 made of n⁺-type Ga₂O₃ by an epitaxial growth method; a cathode electrode 30 is formed on the rear surface of the substrate 10; stripe-shaped trenches TR are periodically formed on the main surface of the drift layer 90 opposite to the rear surface of the substrate 10; and an anode electrode 100 made of nickel (Ni) is formed so as to embed the trenches TR.

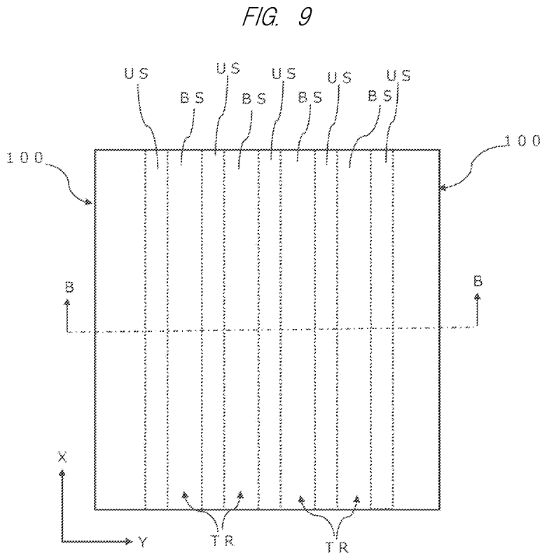

FIG. 9 shows a plan view corresponding to a structure shown in FIG. 8. A B-B cross-section in FIG. 9 corresponds to FIG. 8. As shown in FIG. 9, the trenches TR are formed so as to extend in a direction X in a plan view, and are periodically formed in a direction Y intersecting the direction X. Incidentally, each portion shown by dotted lines in FIG. 9 is a mesa pattern formed so as to protrude from the trench.

At an interface between a bottom surface BS and a side surface SS of the trench TR, a reaction layer 110 made of, for example, NiGaO is formed. Further, gallium oxide and a constituent material (Ni) of the unreacted anode electrode 100 directly contact with each other on an upper surface US of the drift layer 90 periodically existing between the trenches TR.

As in the first embodiment, the second embodiment has a feature in which the electrode material used for the anode electrode 100 is thermally oxidized to form a reaction layer 110 made of an oxide semiconductor (NiGaO) with p-type conductivity at an interface between the anode electrode 100 and the drift layer 90. Further, as in the first embodiment, a metal film such as copper (Cu) or a copper-aluminum alloy (CuAl) can be used as a constituent material of the anode electrode. The electrode material of the anode electrode 100 is not limited to the above, and the metal (Zr, Al, Y, Hf) used in the first modification example can also be used.

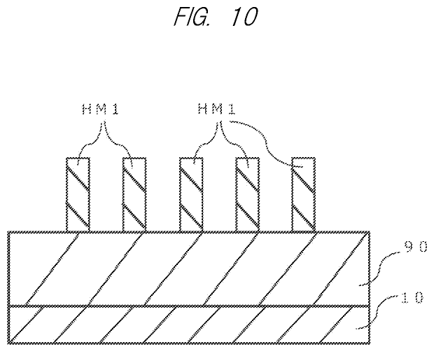

Next, a manufacturing method of the gallium oxide diode of the second embodiment will be described with reference to FIGS. 10 to 15.

First, as in the first embodiment, as shown in FIG. 10, a drift layer 90, which is an n⁻-type semiconductor layer made of Ga₂O₃, is formed on a main surface of the substrate 10 by an epitaxial growth method. The drift layer 90 has a thickness of, for example, 10 microns. The drift layer 90 contains n-type impurities with an impurity concentration lower than that of the Ga₂O₃ substrate 10. The impurity concentration of the drift layer 90 depends on a rated withstand voltage of a device, and is, for example, 1×10¹⁶ cm⁻³. The drift layer 90 serves as a current path that flows in the vertical direction (thickness direction of the substrate 10) in the diode formed later. Further, n-type impurities are introduced into the substrate 10 with a relatively high concentration. For example, tin (Sb) is used as a suitable material for these n-type impurities, and the impurity concentration of the substrate 10 is, for example, 5×10¹⁸ cm⁻³.

Next, hard masks HM1 made of a patterned insulating film are formed on the upper surface of the drift layer 90. In order to form stripe-shaped trenches and mesa patterns in the drift layer 90, the hard masks HM1 are patterned so as to have rectangular stripe shapes each of which has a line width of 1.0 mm and the number of repetitions of 200, for example, as a line and space having an opening size of 3.0 μm and a width of 2.0 μm.

The hard mask HM1 is formed of, for example, a silicon oxide film, a silicon nitride film, or a laminated film thereof. A suitable example of the hard mask HM1 is, for example, a TEOS (Tetra Ethyl Ortho Silicate) film. The hard masks HM1 can be formed by using a CVD method to deposit the TEOS film on the upper surface of the drift layer 90 up to a thickness of about 2.0 μm and then by using a photolithography technique and an etching method to pattern the TEOS film.

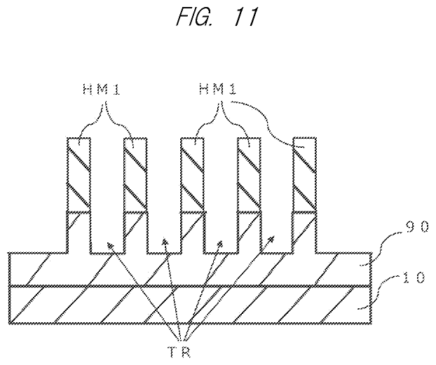

Next, as shown in FIG. 11, the trenches TR are formed by dry etching using the hard mask HM1 as a mask and utilizing a chlorine-based gas (e.g., chlorine boring BCl₂) and by etching the drift layer 90, which is an n⁻-type semiconductor layer made of Ga₂O₃, up to about 2.0 μm.

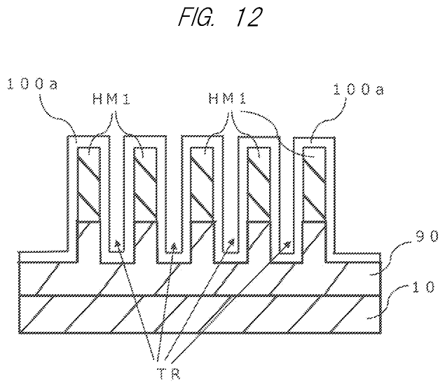

Next, as shown in FIG. 12, a nickel (Ni) film 100a is formed over the substrate 10 by a sputtering method up to about 200 nm. The nickel (Ni) film 100a is formed so as to contact with the bottom surface BS and the side surface SS (corresponding to a side surface of the mesa pattern) of the trench TR.

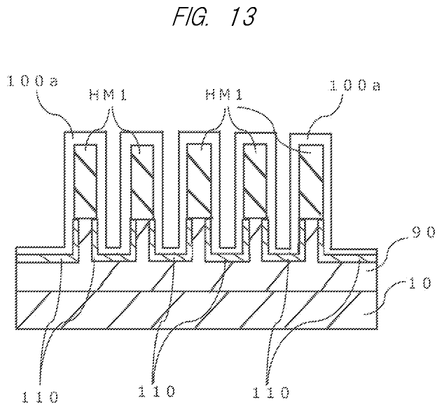

Next, as shown in FIG. 13, a reaction layer 110 made of NiGaO is formed on the bottom surface BS and side surface SS of the trench TR by performing a heat treatment to the nickel film at, for example, 500° C. for 30 minutes in an N₂ atmosphere.

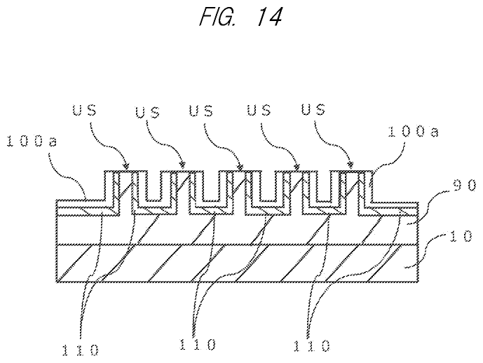

Next, as shown in FIG. 14, the nickel (Ni) film 100a other than the bottom surface BS and side surface SS of the trench TR is removed by, for example, a surface flattening treatment using the CMP method. By this flattening treatment, the hard masks HM1 are also removed, and the upper surface US of the drift layer 90 is partially exposed.

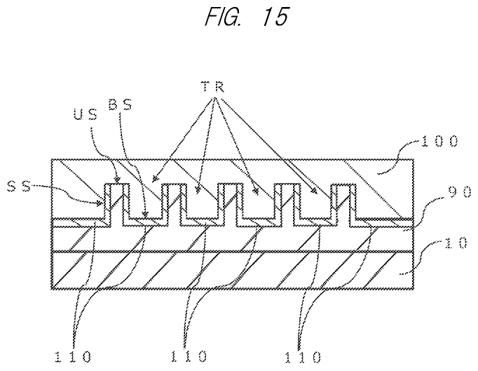

Next, as shown in FIG. 15, the anode electrode 100 is formed by using a sputtering method to deposit, for example, 200 nm of a nickel (Ni) film on the entire surface of the drift layer 90. The nickel (Ni) film 100a earlier formed constitutes the anode electrode 100 integrally with the nickel (Ni) film thereafter formed. In this way, a Ga₂O₃/Ni interface is formed on the upper surface US of the drift layer 90, and a Ga₂O₃/NiGaO/Ni interface is formed on the bottom surface BS and side surface SS of the trench TR.

Next, the rear surface of the substrate 10 is sequentially subjected to grinding, polishing, and CMP steps to thin the substrate 10 from, for example, an initial thickness of 650 μm to a thickness of 200 μm. Next, as shown in FIG. 8, the cathode electrode 30 is formed on the rear surface of the thinned substrate 10. The cathode electrode 30 can be formed, for example, by sequentially laminating and forming a titanium (Ti) film or a gold (Au) film on the rear surface of the substrate 10 and then by performing a heat treatment to it at 300° C. for 1 minute. By performing the above steps, the gallium oxide diode which is the second embodiment is formed.

In the second embodiment, when a high voltage in a reverse direction is applied to the gallium oxide diode, the upper surface US (upper surface of the mesa pattern) of the drift layer 90 is electrically shielded by a Ga₂O₃/NiGaO/Ni junction formed on the bottom surface BS and side surface SS of the trench whose leakage current due to the tunnel current is small (weak), so that an electric field strength about the upper surface of the mesa pattern can be reduced (weakened). When an electric field strength near a Ga₂O₃/Ni junction on the upper surface of the mesa pattern becomes small, a thickness of a Schottky barrier layer becomes thick (large) and the leakage current due to the tunnel current can be reduced.

Therefore, if the structure of the second embodiment is used, the resistance during the forward energization is low in value and use of the Ga₂O₃/Ni junction becomes possible and the trade-off between the on-resistance and the withstand voltage is further improved.

As described above, the invention made by the present inventors has been specifically explained based on the embodiments. However, the present invention is not limited to the above embodiments, and can be variously modified within a range of not departing from the gist thereof.

For example, as the reaction layers 60, 110, the p-type oxide semiconductor layers have been used, but n-type oxide semiconductor layers having a low concentration may be used.

What is claimed is:

1. A semiconductor device having a gallium oxide diode, comprising:
a gallium oxide substrate having an n-type gallium oxide drift layer;
an anode electrode formed over a front surface of the n-type gallium oxide drift layer and made of a metal film;
a cathode electrode formed over a rear surface of the gallium oxide substrate; and
a reaction layer formed between the anode electrode and the n-type gallium oxide drift layer and made of a metal oxide film with p-type conductivity.

2. The semiconductor device according to claim 1,
wherein an electrode material of the anode electrode contains Ni, and the reaction layer contains a NiGaO film.

3. The semiconductor device according to claim 2,
wherein the reaction layer has a thickness of 5 nm or more and 50 nm or less.

4. The semiconductor device according to claim 1,
wherein an electrode material of the anode electrode contains Al, and the reaction layer contains an AlGaO film.

5. The semiconductor device according to claim 4,
wherein the reaction layer has a thickness of 5 nm or more and 50 nm or less.

6. A semiconductor device having a gallium oxide diode, comprising:
an n-type gallium oxide substrate;
an n-type gallium oxide drift layer formed over the n-type gallium oxide substrate and having a lower n-type impurity concentration than that of the n-type gallium oxide substrate;
an anode electrode formed over a front surface of the n-type gallium oxide drift layer and made of a metal film;
a cathode electrode formed over a rear surface of the n-type gallium oxide substrate; and
a reaction layer formed between the anode electrode and the n-type gallium oxide drift layer and made of a metal oxide film with p-type conductivity,
wherein the n-type gallium oxide drift layer has, in a plan view, a plurality of stripe-shaped trenches and a plurality of striped mesa patterns that are defined by the plurality of trenches, and
the reaction layer is formed over a bottom surface and a side surface of each of the plurality of trenches.

7. The semiconductor device according to claim 6,
wherein the reaction layer is not formed over an upper surface of each of the plurality of striped mesa patterns, and the anode electrode directly contacts with the upper surface of each of the plurality of striped mesa patterns.

8. The semiconductor device according to claim 7,
wherein an electrode material of the anode electrode contains Ni, and the reaction layer contains a NiGaO film.

9. The semiconductor device according to claim 7,
wherein an electrode material of the anode electrode contains Al, and the reaction layer contains an AlGaO film.

10. A manufacturing method of a semiconductor device having a gallium oxide diode, the manufacture method comprising:
preparing a gallium oxide substrate having an n-type gallium oxide drift layer;
forming an anode electrode over the n-type gallium oxide drift layer, the anode electrode being made of a metal film;
forming a reaction layer between the anode electrode and the n-type gallium oxide drift layer by performing a heat treatment to the gallium oxide substrate after forming the anode electrode, the reaction layer being made of a metal oxide film with p-type conductivity; and
forming a cathode electrode over a rear surface of the gallium oxide substrate.

11. The manufacturing method of a semiconductor device according to claim 10,
wherein an electrode material of the anode electrode contains Ni, and the reaction layer contains a NiGaO film.

12. The manufacturing method of a semiconductor device according to claim 10,
wherein an electrode material of the anode electrode contains Al, and the reaction layer contains an AlGaO film.
